(19) United States
(12) Patent Application Publication
(10) Pub. No.: US 2025/0199080 A1
(43) Pub. Date: Jun. 19, 2025

(54) SYSTEMS, APPARATUSES, AND METHODS FOR DETERMINING A STATE OF CHARGE OF A BATTERY

(71) Applicant: WaveTech GmbH, Rheinbach (DE)

(72) Inventor: Vesselin Bojidarov Naydenov, Sofia (BG)

(21) Appl. No.: 18/538,484

(22) Filed: Dec. 13, 2023

(51) Int. Cl. G01R 31/388; G01R 31/36; G01R 31/367; G01R 31/371

(52) U.S. Cl. CPC G01R 31/388; G01R 31/3646; G01R 31/367; G01R 31/371

(57) ABSTRACT

Systems, apparatuses, and methods are provided herein. For example, a method included herein includes causing, by a computing device, a battery testing device to apply a plurality of resistive loads to a battery. In some embodiments, each of the plurality of resistive loads are applied for an associated time period of a plurality of time periods. In some embodiments, the method may include receiving, from the battery testing device, a plurality of measured voltages. In some embodiments, each of the plurality of measured voltages is associated with one of the plurality of time periods. In some embodiments, determining, by the computing device, based at least in part on the plurality of measured voltages, a state of charge of the battery.

### FIELD

Embodiments of the present disclosure relate generally to systems, apparatuses, and methods for determining a state of charge of a battery.

### BACKGROUND

Batteries are used in numerous applications. In many applications it is desirable to know the state of charge of a battery, which is a ratio of the battery's capacity (e.g., when the battery is fully charged) and a battery's current charge level (e.g., how much charge the battery currently has). For example, it may be desirable to determine a battery's state of charge to determine how long the battery can supply current before it will need to be recharged.

Systems, apparatuses, and methods for determining the state of charge of a battery in a short time period, in a cost-effective manner, and without causing damage to the battery can be used in numerous applications. Conventional approaches for determining the state of charge of a battery include models, coulomb counting, battery impedance measurements, and monitoring a battery's response to the application of a load to the battery. However, none of these convention approaches are able to determine the state of charge of a battery in a short time period, in a cost-effective manner, and without causing damage to the battery. Accordingly, systems, apparatus, and methods that are able to determine the state of charge of a battery in a short time period, in a cost-effective manner, and without causing damage to the battery would be beneficial.

### BRIEF SUMMARY

Various embodiments described herein relate to systems, apparatuses, and methods for determining a state of charge of a battery.

In accordance with one aspect of the disclosure, a method is provided. In some embodiments, the method may include causing, by a computing device, a battery testing device to apply a plurality of resistive loads to a battery. In some embodiments, each of the plurality of resistive loads are applied for an associated time period of a plurality of time periods. In some embodiments, the method may include receiving, from the battery testing device, a plurality of measured voltages. In some embodiments, each of the plurality of measured voltages is associated with one of the plurality of time periods. In some embodiments, the method may include determining, by the computing device, based at least in part on the plurality of measured voltages, a state of charge of the battery.

In some embodiments, the state of charge of the battery comprises a ratio of a battery capacity associated with the battery and a charge level associated with the battery.

In some embodiments, the method may include causing the state of charge to be displayed on a display panel.

In some embodiments, wherein each of the plurality of resistive loads are applied to a plurality of regions of one or more electrodes associated with the battery.

In some embodiments, the battery testing device is remote.

In some embodiments, each of the plurality of resistive loads is configured to cause the battery to discharge at least one of a plurality of discharge currents.

In some embodiments, at least one of the plurality of measured voltages is an open circuit voltage.

In accordance with another aspect of the disclosure, an apparatus is provided. In some embodiments, the apparatus may include at least one processor and at least one non-transitory memory including computer-coded instructions thereon. In some embodiments, the computer coded instructions, with the at least one processor, cause the apparatus to cause a battery testing device to apply a plurality of resistive loads to a battery. In some embodiments, each of the plurality of resistive loads are applied for an associated time period of a plurality of time periods. In some embodiments, the computer coded instructions, with the at least one processor, cause the apparatus to receive, from the battery testing device, a plurality of measured voltages. In some embodiments, each of the plurality of measured voltages is associated with one of the plurality of time periods. In some embodiments, the computer coded instructions, with the at least one processor, cause the apparatus to determine, based at least in part on the plurality of measured voltages, a state of charge of the battery.

In some embodiments, the state of charge of the battery comprises a ratio of a battery capacity associated with the battery and a charge level associated with the battery.

In some embodiments, the computer coded instructions, with the at least one processor, cause the apparatus to cause the state of charge to be displayed on a display panel.

In some embodiments, wherein each of the plurality of resistive loads are applied to a plurality of regions of one or more electrodes associated with the battery.

In some embodiments, the battery testing device is remote.

In some embodiments, each of the plurality of resistive loads is configured to cause the battery to discharge at least one of a plurality of discharge currents.

In some embodiments, at least one of the plurality of measured voltages is an open circuit voltage.

In accordance with another aspect of the disclosure, an apparatus is provided. In some embodiments, the apparatus may include at least one processor and at least one non-transitory memory including computer-coded instructions thereon. In some embodiments, the computer coded instructions, with the at least one processor, cause the apparatus to apply a plurality of resistive loads to a battery. In some embodiments, each of the plurality of resistive loads are applied for an associated time period of a plurality of time periods. In some embodiments, the computer coded instructions, with the at least one processor, cause the apparatus to determine a plurality of measured voltages. In some embodiments, each of the plurality of measured voltages is associated with one of the plurality of time periods. In some embodiments, the computer coded instructions, with the at least one processor, cause the apparatus to determine based at least in part on the plurality of measured voltages, a state of charge of the battery.

In some embodiments, the state of charge of the battery comprises a ratio of a battery capacity associated with the battery and a charge level associated with the battery.

In some embodiments, the computer coded instructions, with the at least one processor, cause the apparatus to cause the state of charge to be displayed on a display panel.

In some embodiments, wherein each of the plurality of resistive loads are applied to a plurality of regions of one or more electrodes associated with the battery.

In some embodiments, each of the plurality of resistive loads is configured to cause the battery to discharge at least one of a plurality of discharge currents.

In some embodiments, at least one of the plurality of measured voltages is an open circuit voltage.

The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the disclosure in any way. It will be appreciated that the scope of the present disclosure encompasses many potential embodiments in addition to those here summarized, some of which will be further described below.

### BRIEF DESCRIPTION OF THE DRAWINGS

Reference will now be made to the accompanying drawings. The components illustrated in the figures may or may not be present in certain embodiments described herein. Some embodiments may include fewer (or more) components than those shown in the figures in accordance with an example embodiment of the present disclosure.

FIG. 1 illustrates an exemplary environment in which embodiments of the present disclosure may operate;

FIG. 2 illustrates the exemplary environment in which embodiments of the present disclosure may operate;

FIG. 3 illustrates the exemplary environment in which embodiments of the present disclosure may operate;

FIG. 4 illustrates a cross-sectional view of a battery testing device in accordance with one or more embodiments of the present disclosure;

FIG. 5 illustrates a view of one or more electrodes associated with a battery in accordance with one or more embodiments of the present disclosure;

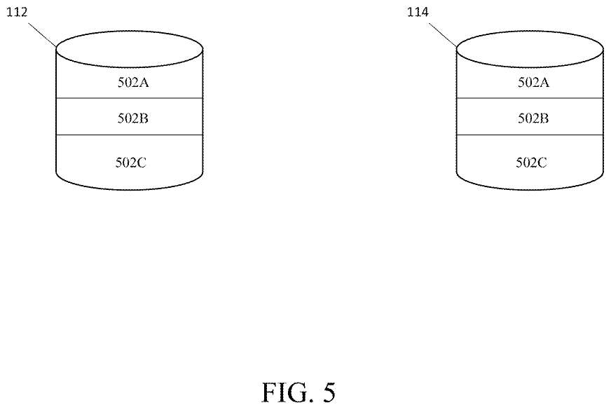

FIG. 6 illustrates a flowchart of an example method in accordance with one or more embodiments of the present disclosure; and

FIG. 7 illustrates a block diagram of an example computer processing device in accordance with one or more embodiments of the present disclosure.

### DETAILED DESCRIPTION

Example embodiments will be described more fully hereinafter with reference to the accompanying drawings, in which some, but not all embodiments of disclosure are shown. Indeed, embodiments of the disclosure may be embodied in many different forms and should not be construed as limited to the embodiments set forth herein; rather, these embodiments are provided so that this disclosure will satisfy applicable legal requirements. Like numbers refer to like elements throughout.

### Overview

Example embodiments disclosed herein address technical problems associated with systems, apparatuses, and methods for determining a state of charge of a battery. As would be understood by one skilled in the field to which this disclosure pertains, there are numerous example scenarios in which a user may use systems, apparatuses, and methods for determining a state of charge of a battery.

In many applications, it is often necessary to determine the state of charge of a battery (e.g., ratio of a battery capacity associated with the battery and a charge level associated with the battery). For example, energy storage systems (e.g., batteries) are used for storing conventional and alternative renewable energy sources. Many of the energy storage systems are batteries (e.g., electrochemical batteries), which result in there being a large number of batteries in the world today. As such, there is a need to manage and monitor these batteries, such as by determining the state of charge of a battery, to ensure the batteries are operating in a prescribed manner (e.g., a battery has a charge level sufficient to perform a task associated with the battery). Additionally, there is a need to determine the state of charge of a battery through direct measurements and under consistent testing conditions, such as temperature, battery operating mode, battery type, battery load level, and/or the like.

An example solution for determining the state of charge of a battery includes using models to determine the state of charge of the battery. For example, a model that includes an adaptive digital filter for calculating the voltage and current values on the battery terminals may be used. Another example solution for determining the state of charge of a battery includes using coulomb counting. For example, coulomb counting may include determining the cumulative charge flowing from a battery by measuring the electric current flow from the battery to a load and the charging flow from a charging device to the battery. Another example solution for determining the state of charge of a battery includes battery impedance measurements and comparative analysis of reference data. For example, this may include measurement of a complex impedance of a battery at multiple different frequencies. Another example solution for determining the state of charge of a battery includes monitoring a battery in response to the application of one or more loads to the battery.

Thus, to address these and/or other issues related to determining the state of charge of a battery, example systems, apparatuses, and/or methods are disclosed herein. For example, an embodiment in this disclosure, described in greater detail below, includes a method that includes causing, by a computing device, a battery testing device to apply a plurality of resistive loads to a battery. In some embodiments, each of the plurality of resistive loads are applied for an associated time period of a plurality of time periods. In some embodiments, the method includes receiving, from the battery testing device, a plurality of measured voltages. In some embodiments, each of the plurality of measured voltages is associated with one of the plurality of time periods. In some embodiments, the method includes determining, by the computing device, based at least in part on the plurality of measured voltages, a state of charge of the battery.

### Example Apparatus

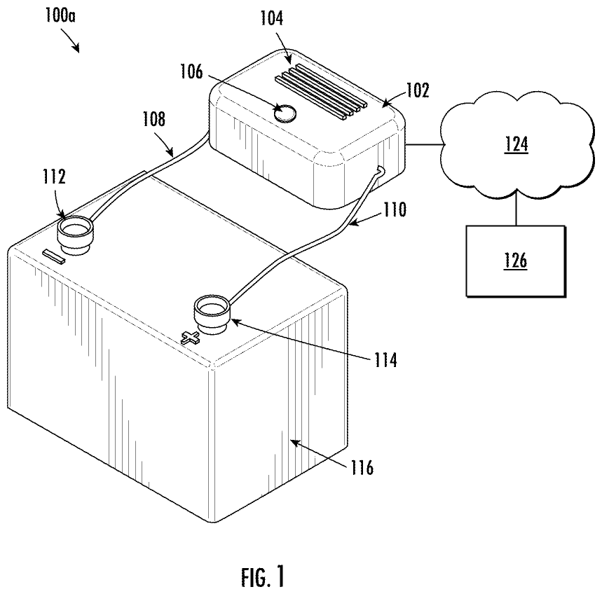

With reference to FIGS. 1-4, embodiments herein provide for systems, apparatuses, and methods for determining a state of charge of a battery. Specifically, each of FIGS. 1-3 illustrate an environment 100 (100a, 100b, 100c) in which embodiments of the present disclosure may operate. It will be appreciated that the environment 100 as well as the illustrations in other figures are each provided as examples of embodiments and should not be construed to narrow the scope or spirit of the disclosure in any way. In this regard, the scope of the disclosure encompasses many potential embodiments in addition to those illustrated and described herein. As such, while each of FIGS. 1-3 illustrates an example of a configuration of an exemplary block diagram of an environment 100 in which embodiments of the present disclosure may operate, numerous other configurations may also be used to implement embodiments of the present disclosure.

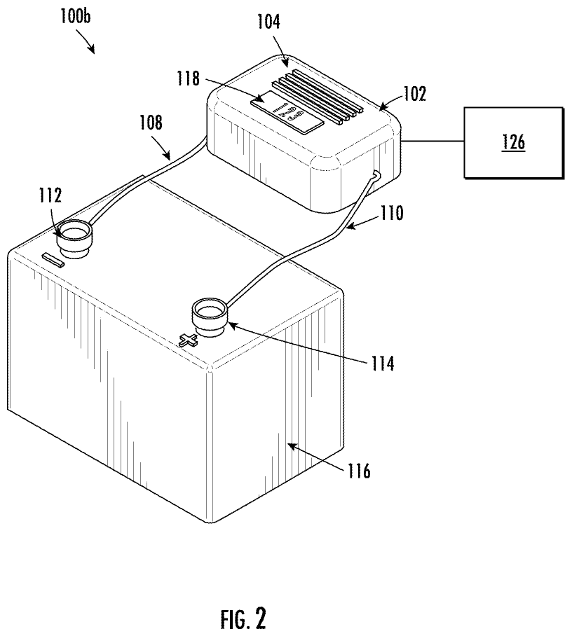

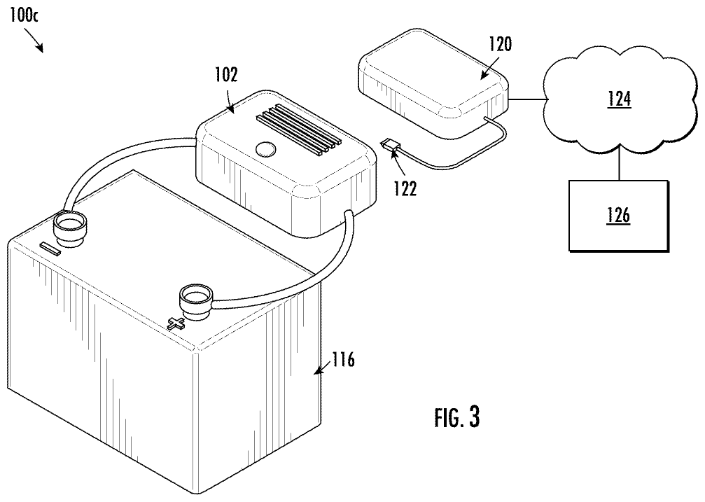

In some embodiments, the environment 100 may include a computing device 126, a battery testing device 102, and/or a battery 116. In some embodiments, the computing device 126 may be in communication with the battery testing device 102. For example, such as depicted in the environment 100a of FIG. 1, the computing device 126 may be in communication with the battery testing device 102 via a network 124. In this regard, for example, the battery testing device 102 may be remote (e.g., remote from the computing device 126). As another example, such as depicted in the environment 100b of FIG. 2, the computing device 126 may be in communication with the battery testing device 102 via a direct connection (e.g., via a wire). As another example, such as depicted in the environment 100c of FIG. 3, the computing device 126 may be in communication with the battery testing device 102 via at least a data link 120 and data link wire 122. Although the computing device 126, the battery testing device 102, the data link 120, and the data link wire 122 are depicted in FIGS. 1-3 as separate components, it would be understood by one skilled in the field to which this disclosure pertains that any one or more of the computing device 126, the battery testing device 102, the data link 120, and/or the data link wire 122 may be combined into one or more components.

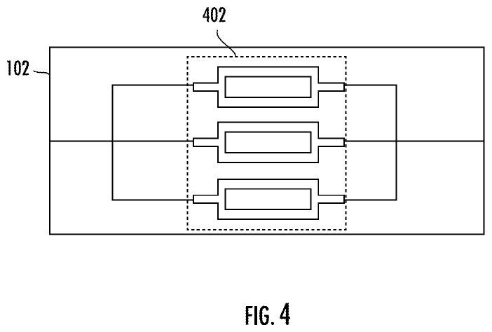

In some embodiments, such as illustrated in FIG. 4, the battery testing device 102 may include a plurality of resistive loads 402. In some embodiments, the battery testing device 102 may include a radiator 104. In this regard, for example, the radiator 104 may be configured to moderate the temperature of the plurality of resistive loads 402, such that the battery testing device 102 does not overheat. In some embodiments, such as depicted in FIG. 1, the battery testing device 102 may include an indicator light 106. The indicator light 106 may be configured to indicate the state of charge of the battery 116. For example, the indicator light 106 may be configured to show a first color (e.g., red) when the battery 116 is discharged, a second color (e.g., yellow) when the battery 116 is half charged, and/or a third color (e.g., green) when the battery 116 is charged. Additionally, or alternatively, such as depicted in FIG. 2, the battery testing device 102 may include a display panel 118 configured to indicate the state of charge of the battery 116 numerically, by words, by symbols, graphically, and/or the like. For example, the display panel 118 may be configured to indicate a charge percentage of the battery 116 (e.g., that the battery is 70% charged).

In some embodiments, the battery testing device 102 may be connected to the battery 116. In this regard, for example, the battery testing device 102 may include a first connector 108 configured to connect the battery testing device 102 to a negative electrode 112 of the battery 116. Additionally, or alternatively, the battery testing device 102 may include a second connector 110 configured to connect the battery testing device 102 to a positive electrode 114 of the battery 116.

In some embodiments, the battery 116 may be a lead battery. For example, the battery 116 may be a lead acid battery, a valve regulated lead-acid battery, and/or the like. In some embodiments, the battery 116 may be a lithium-ion battery. In some embodiments, the battery 116 may be associated with a battery voltage. For example, the battery voltage of the battery 116 may be 8 volts, 12 volts, 24 volts, 32 volts, 36 volts, 48 volts, 96 volts, etc.

In some embodiments, the computing device 126 and/or the battery testing device 102 may be configured to determine the state of charge of the battery 116. In some embodiments, determining the state of charge of the battery 116 may include determining a nominal capacity (Q) of the battery 116. In this regard, for example, the computing device 126 and/or the battery testing device 102 may be configured to determine the nominal capacity (Q) of the battery 116 using equation (1):

$$Q = {\int }_{0}^{{τ}_{p}} {I}_{dch} d τ , \qquad ( 1 )$$

where (I_{dch}) is a discharge current associated with the battery 116, (τₚ) represents an amount of time that it takes for a battery of a certain capacity and at a certain discharge current strength to discharge to reach a predetermined value of a final discharge voltage, and (dτ) represents an actual time variation from the predicted amount of time it takes for a battery to reach a predetermined value of a final discharge voltage and an actual amount of time it takes for a battery to reach a predetermined value of a final discharge voltage.

In some embodiments, the nominal capacity (Q) of the battery 116 may be proportional to the electrochemical equivalent of the active substances from which the electrodes (e.g., positive electrode 114 and negative electrode 112) of battery 116 are made. In some embodiments, the electrochemical equivalent of the active substances from which the electrodes of battery 116 are made represents the amount of electrical energy that can be provided by a unit amount of the active substances. In some embodiments, the battery 116 may be associated with a utilization factor (β). In this regard, for example, it may not be technically feasible to utilize all of the nominal capacity (Q) of the battery 116 and, as such, the utilization factor (β) may be indicative the amount of the nominal capacity (Q) of the battery 116 that can actually be utilized. The utilization factor (β) may be calculated for the battery 116 using equation (2):

$$β = \frac{{QK}^{( 2 )}}{m} , \qquad ( 2 )$$

Where (K⁽²⁾) is the theoretically necessary transformation of the active mass of the electrodes of the battery 116, and (m) is the mass of the active mass (m) of the electrodes.

In some embodiments, the computing device 126 and/or the battery testing device 102 may be configured to determine the actual capacity ( [symbol] _{Ø}) of the battery 116 (e.g., the actual capacity ( [symbol] _{Ø}) being different than the nominal capacity (Q) because it may not be technically feasible to utilize all of the nominal capacity (Q) of the battery 116). In some embodiments, determining the actual capacity ( [symbol] _{Ø}) of the battery 116 may include performing a full discharge of the battery 116 at a specified a discharge current (I_{dch}). In this regard, for example, the actual capacity ( [symbol] _{Ø}) may be determined using equation (3):

$${Q}_{∅} = {I}_{dch} {t}_{dch} , \qquad ( 3 )$$

where I_{dch} is the specified discharge current and t_{dch} is the time it takes to fully discharge the battery 116. In some embodiments, the computing device 126 and/or the battery testing device 102 may be configured to determine a temperature dependent actual capacity ( [symbol] ₜ) of the battery 116 using equation (4):

$${Q}_{t} = \frac{{Q}_{∅}}{1 + α ( {t}_{2} - {t}_{1} )} , \qquad ( 4 )$$

where α is the temperature coefficient (e.g., the temperature may impact the capacity of the battery). In some embodiments, as shown by equations (1)-(4), the temperature dependent actual capacity ( [symbol] ₜ) of the battery 116 may be influenced by a number of factors. For example, the temperature dependent actual capacity ( [symbol] ₜ) of the battery may be influenced by electrochemical equivalent of the active substances from which the electrodes (e.g., positive electrode 114 and negative electrode 112) of the battery 116 are made, the discharge current (I_{dch}) (e.g., the strength of the discharge current (I_{dch})), temperature (e.g., ambient temperature around the battery 116), the utilization factor (β), the battery type (e.g., a lead battery type, a lithium ion battery type, etc.), electrode thickness (e.g., thickness of the positive electrode 114 and/or the negative electrode 112), electrode surface area (e.g., surface area of the positive electrode 114 and/or the negative electrode 112), phase transformation of the battery 116, and/or the like.

In some embodiments, the computing device 126 and/or the battery testing device 102 may be configured to determine the capacity of the battery 116 at a discharge rate of 1 ampere (Q_{dch}), which may be determined using equation (5):

$${Q}_{dch} = {I}^{k} t , \qquad ( 5 )$$

where I is the actual value of the discharge current, t is the actual time it takes to discharge the battery 116 and k is Peukert's constant. In some embodiments, based at least in part on equation (5), the computing device 126 and/or the battery testing device 102 may be configured to determine equation (6) in which the capacity of the battery 116 at a discharge rate of 1 ampere (Q_{dch}) is expressed in terms of the utilization factor (β) (e.g., the utilization factor being the coefficient of usability of the active mass of an electrode (e.g., the positive electrode 114 and/or the negative electrode 112)), the mass of the active mass (m) of the electrodes, and the electrochemical equivalent of the substance at discharge (k⁽⁶⁾):

$${Q}_{dch} = {k}^{( 6 )} β m , \qquad ( 6 )$$

In some embodiments, the computing device 126 and/or the battery testing device 102 may be configured to determine the change in volume of the active mass of the positive electrode 114 based at least in part on a discharge of at least some current from the battery 116 using equation (7):

$${V}_{PAM}^{I} = {V}_{PAM}^{′} + {S}_{PAM}^{′} Δ {δ}_{PAM}^{′} , \qquad ( 7 )$$

where V_{PAM}^{I} is the change in volume of the active mass, V′_{PAM} is the volume of the active mass before discharge of at least some current from the battery 116, S′_{PAM} is a one-sided geometrical surface of the positive electrode 114, and Δδ′_{PAM} is the thickness variation of the positive electrode 114 as a result of the discharge of at least some current from the battery 116.

In some embodiments, the computing device 126 and/or the battery testing device 102 may be configured to determine the change in volume of the active mass of the negative electrode 112 based at least in part on a discharge of at least some current from the battery 116 using equation (8):

$${V}_{NAM}^{II} = {V}_{NAM}^{′′} + {S}_{NAM}^{′′} Δ {δ}_{NAM}^{′′} , \qquad ( 8 )$$

where V_{NAM}^{II} is the change in volume of the active mass, V″_{NAM} is the volume of the active mass before discharge of at least some current from the battery 116, S″_{NAM} is a one-sided geometrical surface of the negative electrode 112, and Δδ″_{NAM} is the thickness variation of the negative electrode 112 as a result of the discharge of at least some current from the battery 116.

In some embodiments, the state of charge of the battery 116 may be determined based at least in part on the thermodynamic and/or electrochemical factors described above (e.g., based at least in part on equations (1)-(8)). In this regard, for example, the factors are the interdependent connection between the capacity of the battery 116 and the strength of the discharge current, the length of time that the discharge current is applied for, the temperature, the usability of the active masses in the battery 116, and/or the like.

In some embodiments, at least in part to determine the state of charge, the computing device 126 may be configured to cause the battery testing device 102 to apply a plurality of resistive loads 402 to the battery 116. Each of the plurality of resistive loads 402 are applied for an associated time period of a plurality of time periods. For example, a first resistive load may be applied to the battery 116 for a first time period and a second resistive load may be applied to the battery 116 for a second time period.

In some embodiments, each of the plurality of resistive loads 402 are applied to at least one of a plurality of regions 502 of one or more electrodes associated with the battery 116 (e.g., negative electrode 112 and/or the positive electrode 114). For example, each of the plurality of resistive loads 402 may be applied to a first region 502A of the plurality of regions 502, a second region 502B of the plurality of regions 502, and/or a third region 502C of the plurality of regions 502.

In some embodiments, a porosity of one or more electrodes associated with the battery 116 may vary throughout one or more electrodes associated with the battery 116. For example, 95 percent of the one or more electrodes associated with the battery 116 may be associated with a first porosity and 5 percent of the one or more electrodes associated with the battery 116 may be associated with a second porosity. In some embodiments, the variation in the porosity of one or more electrodes associated with the battery 116 may impact the state of charge determination. For example, in order to accurately determine the state of charge of the battery 116 it may be desirable to determine the state of charge of the battery based at least in part on resistive loads that have been applied to a region of one or more electrodes associated with the battery 116 most representative of the overall porosity of the one or more electrodes (e.g., the first porosity). In this regard, at least in part by applying each of the plurality of resistive loads 402 to at least one of the plurality of regions 502, the computing device 126 and/or battery testing device 102 may be configured to accurately determine the state of charge of the battery 116 (e.g., the computing device 126 and/or battery testing device 102 may be able to determine the state of charge of the battery 116 such that the porosity of a portion of one or more electrodes associated with the battery 116 does not cause an inaccurate state of charge to be determined).

In some embodiments, the plurality of resistive loads 402 may be applied to the battery 116 in stages. For example, a first portion of the plurality of resistive loads 402 may be applied to the battery 116 in a first stage and a second portion of the plurality of resistive loads 402 may be applied to the battery 116 in a second stage (e.g., if there are four resistive loads in the plurality of resistive loads 402, three resistive loads may be applied in the first stage and one resistive load may be applied in the second stage). In some embodiments, after applying the first portion of the plurality of resistive loads 402 to the battery 116 a preliminary state of charge of the battery may be determined. In some embodiments, after applying the second portion of the plurality of resistive loads 402 to the battery 116, the state of charge of the battery 116 may be determined. In some embodiments, the preliminary state of charge may be the same as the state of charge. In some embodiments the preliminary state of charge may be different than the state of charge.

In some embodiments, by applying the plurality of resistive loads 402 to the battery 116, the battery testing device 102 may be configured to generate a corresponding plurality of discharge currents associated with the battery 116 (e.g., a plurality of currents discharged by the battery 116). In some embodiments, the computing device 126 may be configured to receive, from the battery testing device 102, a plurality of measured voltages. In this regard, for example, the battery testing device 102 may be configured to determine the plurality of measured voltages. In some embodiments, each of the plurality of measured voltages may be associated with one of the plurality of time periods (e.g., the computing device 126 receives a measured voltage for each time period of the plurality of time periods).

In some embodiments, each of the plurality of measured voltages may be associated with one of the plurality of regions 502 (e.g., the computing device 126 receives a measured voltage for each of the plurality of regions 502). In this regard, for example, if the plurality of regions 502 includes three regions and the plurality of time periods includes three time periods, the plurality of measured voltages may include nine measured voltages (e.g., three associated with each of the plurality of regions 502 and/or three associated with each of the plurality of time periods). For example, a matrix may be formed that includes the plurality of measured voltages (e.g., the matrix including the measured voltages for each time period and region). In some embodiments, based at least in part on the plurality of measured voltages, the computing device 126 and/or the battery testing device 102 may be configured to determine the state of charge of the battery. In this regard, for example, by generating the corresponding plurality of discharge currents associated with the battery 116 that are each associated with a particular strength and particular time period while a voltage associated with the battery 116 is measured (e.g., the plurality of measured voltages), the electrochemical reaction of the battery 116 may be assessed (e.g., to determine the state of charge of the battery 116). Said differently, because the electrochemical reaction of the battery 116 is dependent on the strength of the plurality of discharge currents (e.g., as generated by applying the plurality of resistive loads 402) the state of charge of the battery 116 may be determined by determining the plurality of voltages.

In some embodiments, it may be necessary to select the plurality of resistive loads 402 such that the resistive loads can provide the necessary discharge current strengths as well as select the plurality of time periods such that each of the plurality of resistive loads 402 are applied for a necessary time period. In some embodiments, the battery testing device 102 may be able to determine the plurality of measured voltages which are dependent on the capacity of the battery 116 (e.g., such that the state of charge of the battery 116 may be determined). In some embodiments, at least one of the plurality of resistive loads 402 may be selected such that at least one of the plurality of measured voltages is an open circuit voltage (e.g., the restive load is large).

In some embodiments, each of the plurality of measured voltages are dependent on a potential (e.g., a voltage) of the positive electrode 114 and/or a potential of the negative electrode 112. In this regard, since a voltage associated with the battery 116 (e.g., a measured voltage) is the sum of the potential of the positive electrode 114 and the potential of the negative electrode 112, which depend on the strength of the discharge current (e.g., the number of amperes of the discharge current), it means that the voltage associated with the battery 116 also depends on the value of the discharge current. In some embodiments, the value of the discharge current, represents the speed of the occurring electrochemical process of releasing electrical energy from the battery 116 to the plurality of resistive loads 402, which is represented by equation (9):

$$i = {nFk}^{′} {C}_{ox} exp ( - \frac{α n F ε}{RT} ) i = {nFk}^{′} {C}_{red} exp [ - \frac{( 1 - α ) n F ε}{RT} ] , \qquad ( 9 )$$

where (ε) is the potential of the electrode, (n) is the number of electrons involved in the current generating process, (F) is Faraday's constant, (R) is the universal gas constant, (T) is temperature (e.g., temperature in Kelvin), (k′) is the rate constant, (α) is the electrochemical active substance involved in the reaction, (Cₒₓ) is the concentration of the oxidized form of the active substance involved in the reaction, and (C_{red}) is the concentration of the reduced form of the active substance involved in the reaction.

In some embodiments, based on equation (9) showing the dependency of the speed of the electrochemical processes in the battery 116 on the potential of the positive electrode 114 and/or the potential of the negative electrode 112, it follows that as the values of the potential of the positive electrode 114 and/or the potential of the negative electrode 112 is lowered, the voltage associated with the battery 116 correspondingly lowers, meaning that the available charge in the active masses of the battery 116 is diminishing. In this regard, by keeping a constant speed of the electrochemical discharge process of the battery 116, the voltage associated with the battery 116 may be determined from which the state of charge of the battery 116 may be determined. For example, one or more mathematical algorithms may be used to determine the state of charge from the plurality of measured voltages.

In some embodiments, based on the above, the computing device 126 and/or the battery testing device 102 may be configured to run one or more testing routines for determining the state of charge of the battery 116. In some embodiments, the one or more testing routines may each be customized for a particular battery type, battery size, and/or the like. For example, Table 1 below illustrates an example first testing routine for when the battery 116 is a lead battery that has four resistive loads applied to determine the state of charge of the battery 116.

TABLE 1
First phase
Measuring the voltage values of the battery in open circuit

| | | |
|---|---|---|
| Value | Higher or equal to 11.8 V | Lower than 11.8 V |
| Decision | Battery testing continues | Battery for scrap |

Second phase
Formation of a primary matrix of 3 regions, where defined voltage values are set for the
battery. These values in the three regions of the matrix, will be matched by a computational
mathematical algorithm with the values measured at the end of the third step of the second
phase

| | | |
|---|---|---|
| 1^{st} region | 2^{nd} region | 3^{rd} region |
| 11.30-11.59 V | 11.60-11.99 V | 12.00-12.29 V |

| | |
|---|---|
| First step | Applying a resistive load to the battery for 3 seconds to |
| | generate a discharge current of 2.5 A-2 A for 3 seconds. |
| Second step | Applying a resistive load to the battery for 4 seconds to |
| | generate a discharge current of 0.8 A-1 A. |
| Third step | Applying a resistive load to the battery for 4 seconds to |
| | generate a discharge current of 0.5 A-0.65 A. |

Reading the measured voltages of the battery at the
end of the third step of the second phase
of the testing routine

| | |
|---|---|
| Fourth step | Measuring voltage of the battery at the 60^{th} second after |
| | completion of applying the resistive loads to the battery in |
| | the second phase of the testing routine |

Preliminary formation of secondary matrix with
three regions, where three battery voltage
values ranges are set

| | | |
|---|---|---|
| 1^{st} region | 2^{nd} region | 3^{rd} region |
| 12.30-12.59 V | 12.60-12.99 V | 13.00-13.30 V |

The testing routine includes using a mathematical algorithm to perform a comparison of the
measured values within the region of the 60^{th} to 100^{th} second from the beginning of the fourth
step of the second phase of the testing routine, with the values in the three regions of the
secondary matrix. After performing the comparison, the device displays the state of charge of
the battery, such as by presenting the values visually in different colours.

| | | |
|---|---|---|
| Red | Yellow | Green |
| Discharged | Half charged | Charged |

In some embodiments, the computing device 126 and/or the battery testing device 102 may be configured to perform the first testing routine by first performing a first phase of the first testing routine. In some embodiments, the first phase may include measuring the battery 116 in an open circuit configuration. In some embodiments, the first testing routine only proceeds to the second phase if the voltage of the battery 116 is above a voltage threshold (e.g., 10.8 volts).

In some embodiments, the second phase of the testing routine for determining the state of charge of the battery 116 (e.g., when the battery 116 is a lead battery) may include determining at least three measured voltages (e.g., of the plurality of measured voltages) of the battery 116 at the end of three test steps. In this regard, each of the three test steps include applying a different resistive load to the battery 116 for a different time period to obtain one or more different discharge currents. Additionally, or alternatively, each of the three test steps include applying a different resistive load to a different region of the plurality of regions 502 of the battery 116 to obtain one or more different discharge currents. In some embodiments, the particular resistive loads and time periods may be determined at least in part based on equations (1), (3), (4), and (6). In this regard, the resistive loads and/or the time periods may be determined such that the resulting discharge currents would be theoretically possible for the battery 116 to produce and/or such that the battery was not damaged by performing the first testing routine. In some embodiments, at the end of the three test steps, a preliminary state of charge of the battery 116 may be determined.

In some embodiments, the second phase of the testing routine for determining the state of charge of the battery 116 (e.g., when the battery 116 is a lead battery) may include a fourth step, after the first three steps, in which a voltage of the battery 116 is measured for a particular time period (e.g., 30 to 120 seconds) when the battery 116 is in an open circuit configuration. In some embodiments, the measured voltage of the battery 116 at the end of the fourth step gives information on the recovery progress of the battery 116 after being subjected to the three resistive loads in the first three steps of the second phase. In some embodiments, the state of charge of the battery 116 may be determined from the measured voltage of the battery 116 at the end of the fourth step. In some embodiments, the indicator light 106 of the battery testing device 102 may be configured to display the state of charge of the battery 116. Additionally, or alternatively, the display panel 118 may be configured to display the state of charge of the battery 116.

As another example, Table 2 below illustrates an example second testing routine for when the battery 116 is a lithium-ion battery that has four resistive loads applied to determine the state of charge of the battery 116.

TABLE 2
First phase
Measuring the voltage values of the battery in open circuit

| | | |
|---|---|---|
| Value | Higher or equal to 11.2 V | Lower than 11.2 V |
| Decision | Battery testing continues | Battery for scrap |

Second phase
Formation of a primary matrix of 3 regions, where defined voltage values are set for the
battery. These values in the three regions of the matrix, will be matched by a computational
mathematical algorithm with the values measured at the end of the third step of the second
phase

| | | |
|---|---|---|
| 1^{st} region | 2^{nd} region | 3rd region |
| 11.50-12.09 V | 12.10-13.29 V | 13.30-14.20 V |

| | |
|---|---|
| First step | Applying a resistive load to the battery for 3 seconds to |
| | generate a discharge current of 2 A. |
| Second step | Applying a resistive load to the battery for 4 seconds to |
| | generate a discharge current of 5.66 A |
| Third step | Applying a resistive load to the battery for 4 seconds to |
| | generate a discharge current of 8 A |

Reading the measured voltages of the battery at the
end of the third step of the second phase
of the testing routine.

| | |
|---|---|
| Fourth step | Measuring voltage of the battery at the 60^{th} second after |
| | completion of applying the resistive loads to the battery in |
| | the second phase of the testing routine |

Preliminary formation of secondary matrix with
three regions, where three battery voltage
values ranges are set

| | | |
|---|---|---|
| 1^{st} region | 2^{nd} region | 3rd region |
| 13.50-14.19 V | 14.20-14.69 V | 14.70-15.00 V |

The testing routine includes using a mathematical algorithm to perform a comparison of the
measured values within the region of the 10^{th} to 30^{th} second from the beginning of the fourth
step of the second phase of the testing routine, with the values in the three regions of the
secondary matrix. After performing the comparison, the device displays the state of charge of
the battery, such as by presenting a percentage.
State of charge of the battery: %

In some embodiments, the computing device 126 and/or the battery testing device 102 may be configured to perform the second routing by first performing a first phase of the second testing routine. In some embodiments, the first phase may include measuring the battery 116 in an open circuit configuration. In some embodiments, the testing routine only proceeds to the second phase if the voltage of the battery 116 is above a voltage threshold (e.g., 11.2 volts).

In some embodiments, the second phase of the testing routine for determining the state of charge of the battery 116 (e.g., when the battery 116 is a lithium-ion battery) may include determining at least three measured voltages (e.g., of the plurality of measured voltages) of the battery 116 at the end of three test steps. In this regard, each of the three test steps include applying a different resistive load to the battery 116 for a different time period to obtain one or more different discharge currents. Additionally, or alternatively, each of the three test steps include applying a different resistive load to a different region of the plurality of regions 502 of the battery 116 to obtain one or more different discharge currents. In some embodiments, the particular resistive loads and time periods may be determined at least in part based on equations (1), (3), (4), and (6). In this regard, the resistive loads and/or the time periods may be determined such that the resulting discharge currents would be theoretically possible for the battery 116 to produce and/or such that the battery was not damaged by performing the first testing routine. In some embodiments, at the end of the three test steps, a preliminary state of charge of the battery 116 may be determined.

In some embodiments, the second phase of the testing routine for determining the state of charge of the battery 116 (e.g., when the battery 116 is a lithium ion battery) may include a fourth step, after the first three steps, in which a voltage of the battery 116 is measured for a particular time period (e.g., 10 to 30 seconds) when the battery 116 is in an open circuit configuration. In some embodiments, the measured voltage of the battery 116 at the end of the fourth step gives information on the recovery progress of the battery 116 after being subjected to the three resistive loads in the first three steps of the second phase. In some embodiments, the state of charge of the battery 116 may be determined from the measured voltage of the battery 116 at the end of the fourth step. In some embodiments, the indicator light 106 of the battery testing device 102 may be configured to display the state of charge of the battery 116. Additionally, or alternatively, the display panel 118 may be configured to display the state of charge of the battery 116.

### Example Method

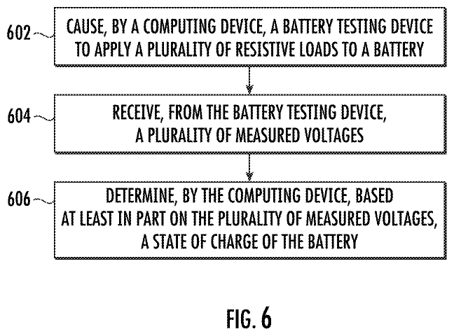

Referring now to FIG. 6, a flowchart providing an example method 600 is illustrated. In this regard, FIG. 6 illustrates operations that may be performed by the computing device 126 and/or the battery testing device 102.

As shown in block 602, the method may include causing, by a computing device, a battery testing device to apply a plurality of resistive loads to a battery. As described above, in some embodiments, determining the state of charge of the battery may include determining a nominal capacity (Q) of the battery. In this regard, for example, the nominal capacity (Q) of the battery may be determined using equation (1):

$$Q = {\int }_{0}^{{τ}_{p}} {I}_{dch} d τ , \qquad ( 1 )$$

where (I_{dch}) is a discharge current associated with the battery, (Tₚ) represents an amount of time that it takes for a battery of a certain capacity and at a certain discharge current strength to discharge to reach a predetermined value of a final discharge voltage, and (dτ) represents an actual time variation from the predicted amount of time it takes for a battery to reach a predetermined value of a final discharge voltage and an actual amount of time it takes for a battery to reach a predetermined value of a final discharge voltage.

In some embodiments, the nominal capacity (Q) of the battery may be proportional to the electrochemical equivalent of the active substances from which the electrodes (e.g., positive electrode and negative electrode) of battery are made. In some embodiments, the electrochemical equivalent of the active substances from which the electrodes of battery are made represents the amount of electrical energy that can be provided by a unit amount of the active substances. In some embodiments, the battery may be associated with a utilization factor (β). In this regard, for example, it may not be technically feasible to utilize all of the nominal capacity (Q) of the battery and, as such, the utilization factor (β) may be indicative the amount of the nominal capacity (Q) of the battery that can actually be utilized. The utilization factor (β) may be calculated for the battery using equation (2):

$$β = \frac{Q {K}^{( 2 )}}{m} , \qquad ( 2 )$$

where (K⁽²⁾) is the theoretically necessary transformation of the active mass of the electrodes of the battery, and (m) is the mass of the active mass (m) of the electrodes.

In some embodiments, the actual capacity ( [symbol] _{Ø}) of the battery may be determined (e.g., the actual capacity ( [symbol] _{Ø}) being different than the nominal capacity (Q) because it may not be technically feasible to utilize all of the nominal capacity (Q) of the battery). In some embodiments, determining the actual capacity ( [symbol] _{Ø}) of the battery may include performing a full discharge of the battery at a specified a discharge current (I_{dch}). In this regard, for example, the actual capacity ( [symbol] _{Ø}) may be determined using equation (3):

$${Q}_{∅} = {I}_{dch} {t}_{dch} , \qquad ( 3 )$$

where I_{dch} is the specified discharge current and t_{dch} is the time it takes to fully discharge the battery. In some embodiments, a temperature dependent actual capacity ( [symbol] ₜ) of the battery may be determined using equation (4):

$${Q}_{t} = \frac{{Q}_{∅}}{1 + α ( {t}_{2} - {t}_{1} )} , \qquad ( 4 )$$

where α is the temperature coefficient (e.g., the temperature may impact the capacity of the battery). In some embodiments, as shown by equations (1)-(4), the temperature dependent actual capacity ( [symbol] ₜ) of the battery may be influenced by a number of factors. For example, the temperature dependent actual capacity ( [symbol] ₜ) of the battery may be influenced by electrochemical equivalent of the active substances from which the electrodes (e.g., positive electrode and negative electrode) of the battery are made, the discharge current (I_{dch}) (e.g., the strength of the discharge current (I_{dch})), temperature (e.g., ambient temperature around the battery), the utilization factor (β), the battery type (e.g., a lead battery type, a lithium ion battery type, etc.), electrode thickness (e.g., thickness of the positive electrode and/or the negative electrode), electrode surface area (e.g., surface area of the positive electrode and/or the negative electrode), phase transformation of the battery, and/or the like.

In some embodiments, the capacity of the battery at a discharge rate of 1 ampere (Q_{dch}), may be determined using equation (5):

$${Q}_{dch} = {I}^{k} t , \qquad ( 5 )$$

where I is the actual value of the discharge current, t is the actual time it takes to discharge the battery and k is Peukert's constant. In some embodiments, based at least in part on equation (5), equation (6) may be determined in which the capacity of the battery at a discharge rate of 1 ampere (Q_{dch}) is expressed in terms of the utilization factor (β), (e.g., the utilization factor being the coefficient of usability of the active mass of an electrode (e.g., the positive electrode and/or the negative electrode)), the mass of the active mass (m) of the electrodes, and the electrochemical equivalent of the substance at discharge (k⁽⁶⁾):

$${Q}_{dch} = {k}^{( 6 )} β m , \qquad ( 6 )$$

In some embodiments, the change in volume of the active mass of the positive electrode may be determined based at least in part on a discharge of at least some current from the battery using equation (7):

$${V}_{PAM}^{I} = {V}_{PAM}^{′} + {S}_{PAM}^{′} Δ {δ}_{PAM}^{′} , \qquad ( 7 )$$

where V_{PAM}^{I} is the change in volume of the active mass, V′_{PAM} is the volume of the active mass before discharge of at least some current from the battery, S′_{PAM} is a one-sided geometrical surface of the positive electrode, and Δδ′_{PAM} is the thickness variation of the positive electrode as a result of the discharge of at least some current from the battery.

In some embodiments, the change in volume of the active mass of the negative electrode may be determined based at least in part on a discharge of at least some current from the battery using equation (8):

$${V}_{NAM}^{II} = {V}_{NAM}^{′′} + {S}_{NAM}^{′′} Δ {δ}_{NAM}^{′′} , \qquad ( 8 )$$

where V_{NAM}^{II} is the change in volume of the active mass, V″_{NAM} is the volume of the active mass before discharge of at least some current from the battery, S″_{NAM} is a one-sided geometrical surface of the negative electrode, and Δδ″_{NAM} is the thickness variation of the negative electrode as a result of the discharge of at least some current from the battery.

In some embodiments, the state of charge of the battery may be determined based at least in part on the thermodynamic and/or electrochemical factors described above (e.g., based at least in part on equations (1)-(8)). In this regard, for example, the factors are the interdependent connection between the capacity of the battery and the strength of the discharge current, the length of time that the discharge current is applied for, the temperature, the usability of the active masses in the battery, and/or the like.

As shown in block 604, the method may include receiving, from the battery testing device, a plurality of measured voltages. As described above, in some embodiments, each of the plurality of resistive loads are applied for an associated time period of a plurality of time periods. For example, a first resistive load may be applied to the battery for a first time period and a second resistive load may be applied to the battery for a second time period.

In some embodiments, each of the plurality of resistive loads are applied to at least one of a plurality of regions of one or more electrodes associated with the battery (e.g., negative electrode and/or the positive electrode). For example, each of the plurality of resistive loads may be applied to a first region of the plurality of regions, a second region of the plurality of regions, and/or a third region of the plurality of regions.

In some embodiments, a porosity of one or more electrodes associated with the battery may vary throughout one or more electrodes associated with the battery. For example, 95 percent of the one or more electrodes associated with the battery may be associated with a first porosity and 5 percent of the one or more electrodes associated with the battery may be associated with a second porosity. In some embodiments, the variation in the porosity of one or more electrodes associated with the battery may impact the state of charge determination. For example, in order to accurately determine the state of charge of the battery it may be desirable to determine the state of charge of the battery based at least in part on resistive loads that have been applied to a region of one or more electrodes associated with the battery most representative of the overall porosity of the one or more electrodes (e.g., the first porosity). In this regard, at least in part by applying each of the plurality of resistive loads to at least one of the plurality of regions, the state of charge of the battery may be accurately determined (e.g., the state of charge of the battery may be determined such that the porosity of a portion of one or more electrodes associated with the battery does not cause an inaccurate state of charge to be determined).

In some embodiments, the plurality of resistive loads may be applied to the battery in stages. For example, a first portion of the plurality of resistive loads may be applied to the battery in a first stage and a second portion of the plurality of resistive loads may be applied to the battery in a second stage (e.g., if there are four resistive loads in the plurality of resistive loads, three resistive loads may be applied in the first stage and one resistive load may be applied in the second stage). In some embodiments, after applying the first portion of the plurality of resistive loads to the battery a preliminary state of charge of the battery may be determined. In some embodiments, after applying the second portion of the plurality of resistive loads to the battery, the state of charge of the battery may be determined. In some embodiments, the preliminary state of charge may be the same as the state of charge. In some embodiments the preliminary state of charge may be different than the state of charge.

In some embodiments, by applying the plurality of resistive loads to the battery, a corresponding plurality of discharge currents associated with the battery may be generated (e.g., a plurality of currents discharged by the battery). In some embodiments, a plurality of measured voltages may be received. In some embodiments, each of the plurality of measured voltages may be associated with one of the plurality of time periods.

In some embodiments, each of the plurality of measured voltages may be associated with one of the plurality of regions. In this regard, for example, if the plurality of regions includes three regions and the plurality of time periods includes three time periods, the plurality of measured voltages may include nine measured voltages (e.g., three associated with each of the plurality of regions and/or three associated with each of the plurality of time periods). For example, a matrix may be formed that includes the plurality of measured voltages (e.g., the matrix including the measured voltages for each time period and region).

As shown in block 606, the method may include determining, by the computing device, based at least in part on the plurality of measured voltages, a state of charge of the battery. As described above, by generating the corresponding plurality of discharge currents associated with the battery that are each associated with a particular strength and particular time period while a voltage associated with the battery is measured (e.g., the plurality of measured voltages), the electrochemical reaction of the battery may be assessed (e.g., to determine the state of charge of the battery). Said differently, because the electrochemical reaction of the battery is dependent on the strength of the plurality of discharge currents (e.g., as generated by applying the plurality of resistive loads) the state of charge of the battery may be determined by determining the plurality of voltages.

In some embodiments, it may be necessary to select the plurality of resistive loads such that the resistive loads can provide the necessary discharge current strengths as well as select the plurality of time periods such that each of the plurality of resistive loads are applied for a necessary time period. In some embodiments, the plurality of measured voltages may be dependent on the capacity of the battery (e.g., such that the state of charge of the battery may be determined). In some embodiments, at least one of the plurality of resistive loads may be selected such that at least one of the plurality of measured voltages is an open circuit voltage (e.g., the restive load is large).

In some embodiments, each of the plurality of measured voltages are dependent on a potential (e.g., a voltage) of the positive electrode and/or a potential of the negative electrode. In this regard, since a voltage associated with the battery (e.g., a measured voltage) is the sum of the potential of the positive electrode and the potential of the negative electrode, which depend on the strength of the discharge current (e.g., the number of amperes of the discharge current), it means that the voltage associated with the battery also depends on the value of the discharge current. In some embodiments, the value of the discharge current, represents the speed of the occurring electrochemical process of releasing electrical energy from the battery to the plurality of resistive loads, which is represented by equation (9):

$$i = {nFk}^{′} {C}_{ox} exp ( - \frac{α n F ε}{RT} ) i = {nFk}^{′} {C}_{red} exp [ - \frac{( 1 - α ) n F ε}{RT} ] , \qquad ( 9 )$$

where (ε) is the potential of the electrode, (n) is the number of electrons involved in the current generating process, (F) is Faraday's constant, (R) is the universal gas constant, (T) is temperature (e.g., temperature in Kelvin), (k′) is the rate constant, (α) is the electrochemical active substance involved in the reaction, (Cₒₓ) is the concentration of the oxidized form of the active substance involved in the reaction, and (C_{red}) is the concentration of the reduced form of the active substance involved in the reaction.

In some embodiments, based on equation (9) showing the dependency of the speed of the electrochemical processes in the battery on the potential of the positive electrode and/or the potential of the negative electrode, it follows that as the values of the potential of the positive electrode and/or the potential of the negative electrode is lowered, the voltage associated with the battery correspondingly lowers, meaning that the available charge in the active masses of the battery is diminishing. In this regard, by keeping a constant speed of the electrochemical discharge process of the battery, the voltage associated with the battery may be determined from which the state of charge of the battery may be determined. For example, one or more mathematical algorithms may be used to determine the state of charge from the plurality of measured voltages.

### Example Computer Processing Device

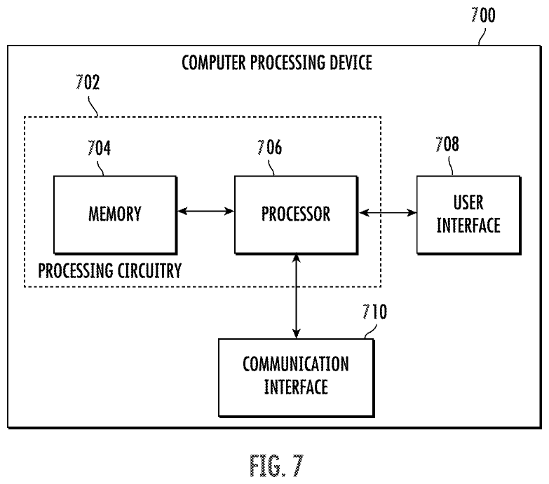

With reference to FIG. 7, a block diagram of an example computer processing device 700 is illustrated in accordance with some example embodiments. In some embodiments, the computing device 126, the battery testing device 102, and/or other devices may be embodied as one or more computer processing devices, such as the computer processing device 700 in FIG. 7. However, it should be noted that the components, devices, or elements illustrated in and described with respect to FIG. 7 below may not be mandatory and thus one or more may be omitted in certain embodiments. Additionally, some embodiments may include further or different components, devices or elements beyond those illustrated in and described with respect to FIG. 7.

The computer processing device 700 may include or otherwise be in communication with processing circuitry 702 that is configurable to perform actions in accordance with one or more embodiments disclosed herein. In this regard, the processing circuitry 702 may be configured to perform and/or control performance of one or more functionalities of the computer processing device 700 in accordance with various embodiments, and thus may provide means for performing functionalities of the computer processing device 700 in accordance with various embodiments. The processing circuitry 702 may be configured to perform data processing, application execution and/or other processing and management services according to one or more embodiments. In some embodiments, the computer processing device 700 or a portion(s) or component(s) thereof, such as the processing circuitry 702, may be embodied as or comprise a chip or chip set. In other words, the computer processing device 700 or the processing circuitry 702 may comprise one or more physical packages (e.g., chips) including materials, components and/or wires on a structural assembly (e.g., a baseboard). The structural assembly may provide physical strength, conservation of size, and/or limitation of electrical interaction for component circuitry included thereon. The computer processing device 700 or the processing circuitry 702 may therefore, in some cases, be configured to implement an embodiment of the disclosure on a single chip or as a single “system on a chip.” As such, in some cases, a chip or chipset may constitute means for performing one or more operations for providing the functionalities described herein.

In some embodiments, the processing circuitry 702 may include a processor 706 and, in some embodiments, such as that illustrated in FIG. 7, may further include memory 704. The processing circuitry 702 may be in communication with or otherwise control a user interface 708 and/or a communication interface 710. As such, the processing circuitry 702 may be embodied as a circuit chip (e.g., an integrated circuit chip) configured (e.g., with hardware, software or a combination of hardware and software) to perform operations described herein.

The processor 706 may be embodied in a number of different ways. For example, the processor 706 may be embodied as various processing means such as one or more of a microprocessor or other processing element, a coprocessor, a controller or various other computing or processing devices including integrated circuits such as, for example, an ASIC (application specific integrated circuit), an FPGA (field programmable gate array), or the like. Although illustrated as a single processor, it will be appreciated that the processor 706 may comprise a plurality of processors. The plurality of processors may be in operative communication with each other and may be collectively configured to perform one or more functionalities of the computer processing device 700 as described herein. In some embodiments, the processor 706 may be configured to execute instructions stored in the memory 704 or otherwise accessible to the processor 706. As such, whether configured by hardware or by a combination of hardware and software, the processor 706 may represent an entity (e.g., physically embodied in circuitry—in the form of processing circuitry 702) capable of performing operations according to embodiments of the present disclosure while configured accordingly. Thus, for example, when the processor 706 is embodied as an ASIC, FPGA or the like, the processor 706 may be specifically configured hardware for conducting the operations described herein. Alternatively, as another example, when the processor 706 is embodied as an executor of software instructions, the instructions may specifically configure the processor 706 to perform one or more operations described herein.

In some embodiments, the memory 704 may include one or more non-transitory memory devices such as, for example, volatile and/or non-volatile memory that may be either fixed or removable. In this regard, the memory 704 may comprise a non-transitory computer-readable storage medium. It will be appreciated that while the memory 704 is illustrated as a single memory, the memory 704 may comprise a plurality of memories. The memory 704 may be configured to store information, data, applications, instructions and/or the like for enabling the computer processing device 700 to carry out various functions in accordance with one or more embodiments. For example, the memory 704 may be configured to buffer input data for processing by the processor 706. Additionally, or alternatively, the memory 704 may be configured to store instructions for execution by the processor 706. As yet another alternative, the memory 704 may include one or more databases that may store a variety of files, contents or data sets. Among the contents of the memory 704, applications may be stored for execution by the processor 706 in order to carry out the functionality associated with each respective application. In some cases, the memory 704 may be in communication with one or more of the processor 706, user interface 708, and/or communication interface 710 via a bus(es) for passing information among components of the computer processing device 700.

The user interface 708 may be in communication with the processing circuitry 702 to receive an indication of a user input at the user interface 708 and/or to provide an audible, visual, mechanical or other output to the user. As such, the user interface 708 may include, for example, a keyboard, a mouse, a display, a touch screen display, a microphone, a speaker, and/or other input/output mechanisms. As such, the user interface 708 may, in some embodiments, provide means for a user to access and interact with the computing device 126, the battery testing device 102, and/or other devices.

The communication interface 710 may include one or more interface mechanisms for enabling communication with other devices and/or networks. In some cases, the communication interface 710 may be any means such as a device or circuitry embodied in either hardware, or a combination of hardware and software that is configured to receive and/or transmit data from/to a network and/or any other device or module in communication with the processing circuitry 702. By way of example, the communication interface 710 may be configured to enable the computing device 126, the battery testing device 102, and/or other devices to communicate with each other. Accordingly, the communication interface 710 may, for example, include an antenna (or multiple antennas) and supporting hardware and/or software for enabling communications with a wireless communication network (e.g., a wireless local area network, cellular network, global positing system network, and/or the like) and/or a communication modem or other hardware/software for supporting communication via cable, digital subscriber line (DSL), universal serial bus (USB), Ethernet or other methods.

Many modifications and other embodiments of the inventions set forth herein will come to mind to one skilled in the art to which these inventions pertain having the benefit of teachings presented in the foregoing descriptions and the associated drawings. Although the figures only show certain components of the apparatus and systems described herein, it is understood that various other components may be used in conjunction with the system. Therefore, it is to be understood that the inventions are not to be limited to the specific embodiments disclosed and that modifications and other embodiments are intended to be included within the scope of the appended claims. Moreover, the steps in the method described above may not necessarily occur in the order depicted in the accompanying diagrams, and in some cases one or more of the steps depicted may occur substantially simultaneously, or additional steps may be involved. Although specific terms are employed herein, they are used in a generic and descriptive sense only and not for purposes of limitation.

While various embodiments in accordance with the principles disclosed herein have been shown and described above, modifications thereof may be made by one skilled in the art without departing from the spirit and the teachings of the disclosure. The embodiments described herein are representative only and are not intended to be limiting. Many variations, combinations, and modifications are possible and are within the scope of the disclosure. Alternative embodiments that result from combining, integrating, and/or omitting features of the embodiment(s) are also within the scope of the disclosure. Accordingly, the scope of protection is not limited by the description set out above.

Additionally, the section headings used herein are provided for consistency with the suggestions under 37 C.F.R. 1.77 or to otherwise provide organizational cues. These headings shall not limit or characterize the invention(s) set out in any claims that may issue from this disclosure.

Use of broader terms such as “comprises,” “includes,” and “having” should be understood to provide support for narrower terms such as “consisting of,” “consisting essentially of,” and “comprised substantially of” Use of the terms “optionally,” “may,” “might,” “possibly,” and the like with respect to any element of an embodiment means that the element is not required, or alternatively, the element is required, both alternatives being within the scope of the embodiment(s). Also, references to examples are merely provided for illustrative purposes, and are not intended to be exclusive.

That which is claimed:

1. A method comprising:
causing, by a computing device, a battery testing device to apply a plurality of resistive loads to a battery, wherein each of the plurality of resistive loads are applied for an associated time period of a plurality of time periods;
receiving, from the battery testing device, a plurality of measured voltages, wherein each of the plurality of measured voltages is associated with one of the plurality of time periods; and
determining, by the computing device, based at least in part on the plurality of measured voltages, a state of charge of the battery.

2. The method of claim 1, wherein the state of charge of the battery comprises a ratio of a battery capacity associated with the battery and a charge level associated with the battery.

3. The method of claim 1, further comprising:
causing the state of charge to be displayed on a display panel.

4. The method of claim 1, wherein each of the plurality of resistive loads are applied to a plurality of regions of one or more electrodes associated with the battery.

5. The method of claim 1, wherein the battery testing device is remote.

6. The method of claim 1, wherein each of the plurality of resistive loads is configured to cause the battery to discharge at least one of a plurality of discharge currents.

7. The method of claim 1, wherein at least one of the plurality of measured voltages is an open circuit voltage.

8. An apparatus comprising at least one processor and at least one non-transitory memory including computer-coded instructions thereon, the computer coded instructions, with the at least one processor, cause the apparatus to:
cause a battery testing device to apply a plurality of resistive loads to a battery, wherein each of the plurality of resistive loads are applied for an associated time period of a plurality of time periods;
receive, from the battery testing device, a plurality of measured voltages, wherein each of the plurality of measured voltages is associated with one of the plurality of time periods; and
determine based at least in part on the plurality of measured voltages, a state of charge of the battery.

9. The apparatus of claim 8, wherein the state of charge of the battery comprises a ratio of a battery capacity associated with the battery and a charge level associated with the battery.

10. The apparatus of claim 8, wherein the computer coded instructions, with the at least one processor, cause the apparatus to:
cause the state of charge to be displayed on a display panel.

11. The apparatus of claim 8, wherein each of the plurality of resistive loads are applied to a plurality of regions of one or more electrodes associated with the battery.

12. The apparatus of claim 8, wherein the battery testing device is remote.

13. The apparatus of claim 8, wherein each of the plurality of resistive loads is configured to cause the battery to discharge at least one of a plurality of discharge currents.

14. The apparatus of claim 8, wherein at least one of the plurality of measured voltages is an open circuit voltage.

15. An apparatus comprising at least one processor and at least one non-transitory memory including computer-coded instructions thereon, the computer coded instructions, with the at least one processor, cause the apparatus to:
apply a plurality of resistive loads to a battery, wherein each of the plurality of resistive loads are applied for an associated time period of a plurality of time periods;
determine a plurality of measured voltages, wherein each of the plurality of measured voltages is associated with one of the plurality of time periods; and
determine based at least in part on the plurality of measured voltages, a state of charge of the battery.

16. The apparatus of claim 15, wherein the state of charge of the battery comprises a ratio of a battery capacity associated with the battery and a charge level associated with the battery.

17. The apparatus of claim 15, wherein the computer coded instructions, with the at least one processor, cause the apparatus to:
cause the state of charge to be displayed on a display panel.

18. The apparatus of claim 15, wherein each of the plurality of resistive loads are applied to a plurality of regions of one or more electrodes associated with the battery.

19. The apparatus of claim 15, wherein each of the plurality of resistive loads is configured to cause the battery to discharge at least one of a plurality of discharge currents.

20. The apparatus of claim 15, wherein at least one of the plurality of measured voltages is an open circuit voltage.
